(19) United States
(12) Patent Application Publication
(10) Pub. No.: US 2009/0027234 A1
(43) Pub. Date: Jan. 29, 2009

(54) Computer Equipment for Car

(76) Inventor: Hsu-Li Lee, Kaohsiang City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/781,791

(22) Filed: Jul. 23, 2007

(51) Int. Cl. H03K 17/94

(52) U.S. Cl. 341/22

(57) ABSTRACT

A computer equipment for a car includes a display mounted in a car, a host system mounted in the car, and a keyboard mounted in the car and connected between the display and the host system to connect the host system to the display. Thus, after the car is stopped, a user can control operation of the host system of the computer equipment by operating the keyboard to co-operate with the display so as to perform the functions of a computer, such as, the E-mail or word processing functions. In addition, the display functions as a monitor of the computer equipment, thereby enhancing the versatility of the display.

### BACKGROUND OF THE INVENTION

1. Field of the Invention

The present invention relates to a computer equipment and, more particularly, to a computer equipment for a car.

2. Description of the Related Art

A conventional display 12 in accordance with the prior art shown in FIG. 5 is mounted on a central control unit 11 of a car 1. Thus, the display 12 is used to play the music, video, CD, VCD or DVD. In addition, the display 12 is used to function as a monitor of a satellite navigation for showing information of the satellite navigation. However, the display 12 cannot perform the functions of a computer, thereby limiting the versatility of the display 12.

### BRIEF SUMMARY OF THE INVENTION

In accordance with the present invention, there is provided a computer equipment, comprising a display mounted in a car, a host system mounted in the car, and a keyboard mounted in the car and connected between the display and the host system to connect the host system to the display.

Preferably, the keyboard is mounted on a steering wheel of the car.

Preferably, the keyboard is located above a glove compartment of the car.

Preferably, the keyboard is mounted on a cover of a glove compartment of the car.

Preferably, the keyboard is mounted on a rear side of a backrest of a seat of the car.

The primary objective of the present invention is to provide a computer equipment for a car, wherein after the car is stopped, a user can control operation of the host system of the computer equipment by operating the keyboard to co-operate with the display so as to perform the functions of a computer, such as, the E-mail or word processing functions.

Another objective of the present invention is to provide a computer equipment for a car, wherein the display functions as a monitor of the computer equipment, thereby enhancing the versatility of the display.

A further objective of the present invention is to provide a computer equipment for a car, wherein the keyboard can be mounted on the steering wheel, the glove compartment, the cover of the glove compartment or the backrest of the seat, so that the keyboard can be operated easily by the driver or the passenger so as to control operation of the host system of the computer equipment easily and conveniently, thereby facilitating the driver or the passenger operating the computer equipment, and thereby providing a comfortable sensation to the driver or the passenger.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a computer equipment for a car in accordance with the preferred embodiment of the present invention.

FIG. 2 is a perspective view of a computer equipment for a car in accordance with another preferred embodiment of the present invention.

FIG. 3 is a perspective view of a computer equipment for a car in accordance with another preferred embodiment of the present invention.

FIG. 4 is a perspective view of a computer equipment for a car in accordance with another preferred embodiment of the present invention.

FIG. 5 is a perspective view of a conventional display in accordance with the prior art.

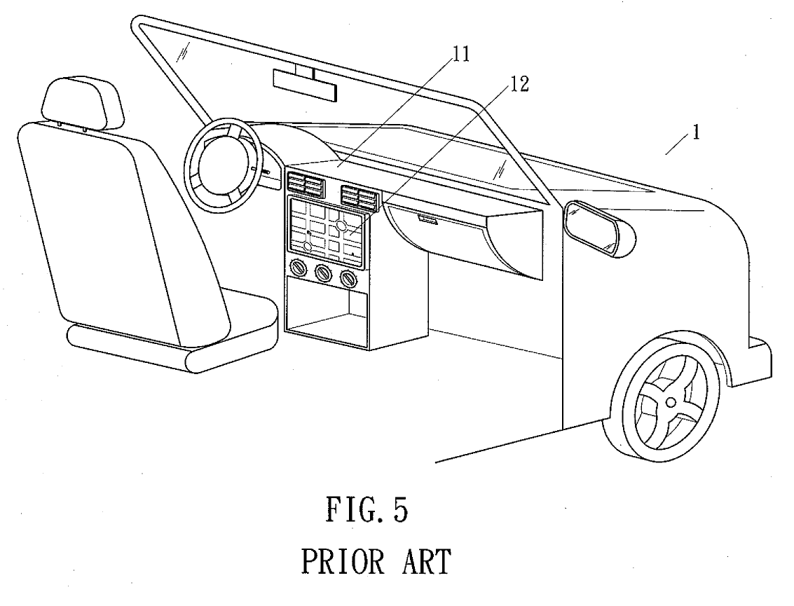

### DETAILED DESCRIPTION OF THE INVENTION

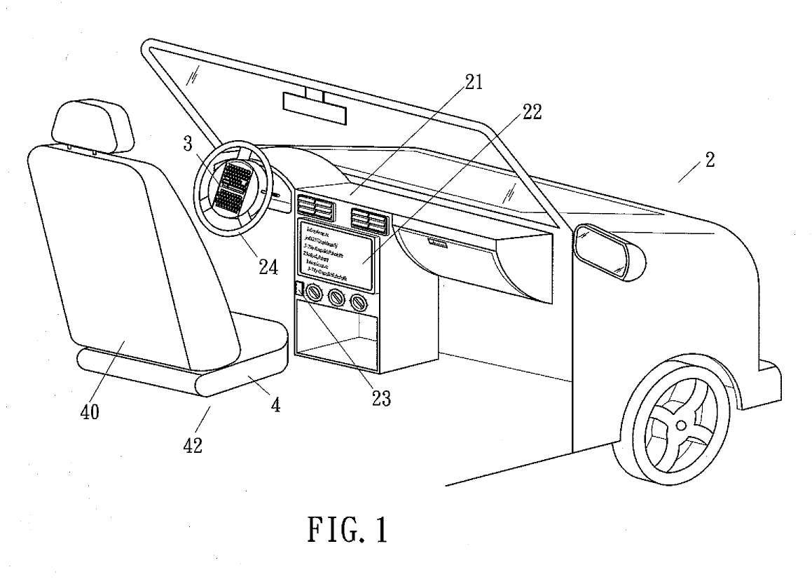

Referring to the drawings and initially to FIG. 1, a computer equipment for a car in accordance with the preferred embodiment of the present invention comprises a display 22 mounted in a car 2, a host system 23 mounted in the car 2, and a keyboard 3 mounted in the car 2 and connected between the display 22 and the host system 23 to connect the host system 23 to the display 22.

The display 22 is mounted on a central control unit 21 of the car 2. The display 22 is available for showing information of a satellite navigation and can be used to play the music, video, CD, VCD or DVD. The host system 23 is located under the central control unit 21 of the car 2 and the display 22 and includes a host (not shown) and a control switch (not shown) to control operation of the host. Preferably, the host of the host system 23 is mounted in a trunk (not shown) of the car 2 or in a space 42 located under a seat 4 of the car 2. Alternatively, the host of the host system 23 is directly located under the display 22.

In the preferred embodiment of the present invention, the keyboard 3 is mounted on a steering wheel 24 of the car 2 and located at a central position of the steering wheel 24. The keyboard 3 is connected to the host of the host system 23 by wires (not shown) or in a wireless transmission manner.

In operation, after the host system 23 is started and operated, a user can control operation of the host system 23 of the computer equipment by operating the keyboard 3 to co-operate with the display 22 so as to perform the functions of a computer, such as, the E-mail or word processing functions.

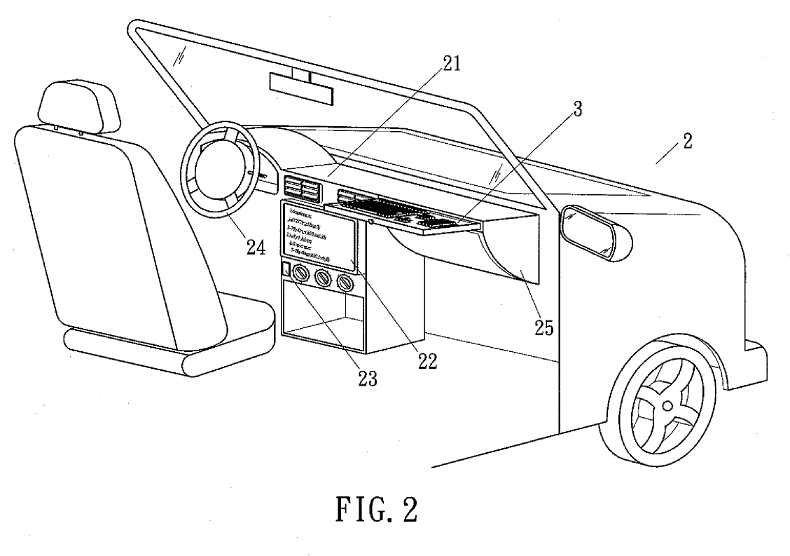

As shown in FIG. 2, the keyboard 3 is located above a glove compartment 25 of the car 2. Thus, the keyboard 3 is movable freely relative to the glove compartment 25 to expand outwardly or retract inwardly.

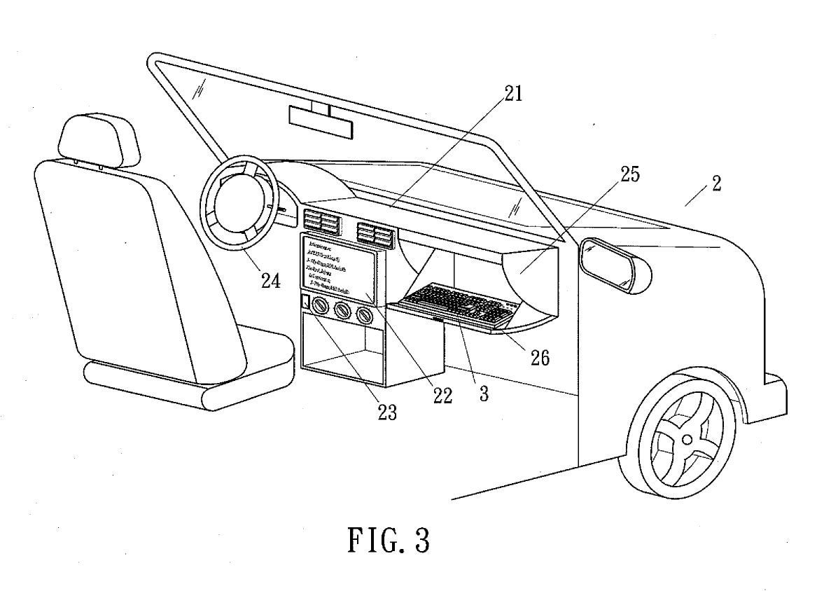

As shown in FIG. 3, the keyboard 3 is mounted on a cover 26 of the glove compartment 25 of the car 2. Thus, the keyboard 3 is movable with the cover 26 to expand outwardly or retract inwardly.

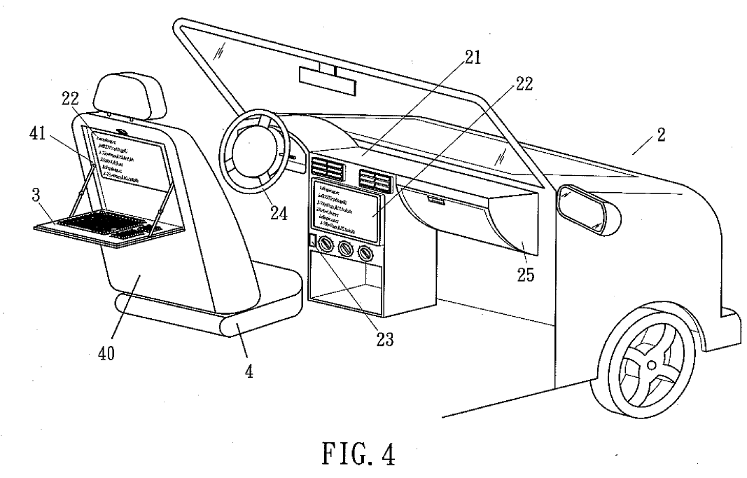

As shown in FIG. 4, the keyboard 3 is mounted on a rear side of a backrest 40 of the seat 4 of the car 2. Thus, the keyboard 3 is movable relative to the backrest 40 of the seat 4 to expand outwardly or retract inwardly. The rear side of the backrest 40 is formed with a receiving space 41 to receive the keyboard 3 and the display 22.

Accordingly, after the car 2 is stopped, a user can control operation of the host system 23 of the computer equipment by operating the keyboard 3 to co-operate with the display 22 so as to perform the functions of a computer, such as, the E-mail or word processing functions. In addition, the display 22 functions as a monitor of the computer equipment, thereby enhancing the versatility of the display 22. Further, the keyboard 3 can be mounted on the steering wheel 24, the glove compartment 25, the cover 26 of the glove compartment 25 or the backrest 40 of the seat 4, so that the keyboard 3 can be operated easily by the driver or the passenger so as to control operation of the host system 23 of the computer equipment easily and conveniently, thereby facilitating the driver or the passenger operating the computer equipment, and thereby providing a comfortable sensation to the driver or the passenger.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A computer equipment, comprising:
a display mounted in a car;
a host system mounted in the car;
a keyboard mounted in the car and connected between the display and the host system to connect the host system to the display.

2. The computer equipment in accordance with claim 1, wherein the keyboard is mounted on a steering wheel of the car.

3. The computer equipment in accordance with claim 2, wherein the keyboard is located at a central position of the steering wheel.

4. The computer equipment in accordance with claim 1, wherein the keyboard is located above a glove compartment of the car.

5. The computer equipment in accordance with claim 4, wherein the keyboard is movable freely relative to the glove compartment to expand outwardly or retract inwardly.

6. The computer equipment in accordance with claim 1, wherein the keyboard is mounted on a cover of a glove compartment of the car.

7. The computer equipment in accordance with claim 6, wherein the keyboard is movable with the cover to expand outwardly or retract inwardly.

8. The computer equipment in accordance with claim 1, wherein the keyboard is mounted on a rear side of a backrest of a seat of the car.

9. The computer equipment in accordance with claim 8, wherein the keyboard is movable relative to the backrest of the seat to expand outwardly or retract inwardly.

10. The computer equipment in accordance with claim 9, wherein the rear side of the backrest is formed with a receiving space to receive the keyboard.

11. The computer equipment in accordance with claim 10, wherein the display is received in the receiving space.

12. The computer equipment in accordance with claim 1, wherein the display is mounted on a central control unit of the car.

13. The computer equipment in accordance with claim 12, wherein the host system is located under the central control unit of the car and the display.

14. The computer equipment in accordance with claim 1, wherein the host system is mounted in a space located under a seat of the car.

15. The computer equipment in accordance with claim 1, wherein the host system is directly located under the display.
